(19) United States
(12) Patent Application Publication
(10) Pub. No.: US 2014/0001434 A1
(43) Pub. Date: Jan. 2, 2014

(54) LIGHT EMITTING DIODE STRUCTURE AND MANUFACTURING METHOD THEREOF

(71) Applicant: Lextar Electronics Corporation, Hsinchu (TW)

(72) Inventor: Ming-Sheng Chen, Changhua County (TW)

(73) Assignee: Lextar Electronics Corporation, Hsinchu (TW)

(21) Appl. No.: 13/893,381

(22) Filed: May 14, 2013

(30) Foreign Application Priority Data
Jun. 28, 2012 (TW) 101123245

(51) Int. Cl. H01L 33/04; H01L 33/32

(52) U.S. Cl. CPC H01L 33/04; H01L 33/32
USPC 257/13; 438/46

(57) ABSTRACT

A light-emitting diode structure and a manufacturing method thereof are provided. The structure includes a semiconductor substrate, a first type semiconductor layer, a light-emitting layer, a second type semiconductor layer, an electrode contact layer, a positive electrode and a negative electrode. A stacking layer consisting of the first type semiconductor layer, the light-emitting layer, the second type semiconductor layer and the electrode contact layer is formed on the semiconductor substrate, and a first opening penetrates the electrode contact layer and exposes a part of the second type semiconductor layer. The positive electrode is formed in the first opening. A part of the first type semiconductor layer, the light-emitting layer, the second type semiconductor layer and the electrode contact layer is removed to form a platform structure. The negative electrode is formed on the exposed surface of the first type semiconductor layer.

This application claims the benefit of Taiwan application Serial No. 101123245, filed Jun. 28, 2012, the subject matter of which is incorporated herein by reference.

### BACKGROUND OF THE INVENTION

1. Field of the Invention

The invention relates in general to a light-emitting diode (LED) structure and a manufacturing method thereof, and more particularly to an LED structure capable of spreading and conducting the input current and a manufacturing method thereof.

2. Description of the Related Art

Light emitting diode (LED) relates to a solid state light-emitting element made from a semiconductor material. LED, having the features of small volume, low degree of heating generation, high lamination, low power consumption, long lifespan and being suitable for mass production, so the light emitting diode has been widely used as a lighting source for various lighting devices or back light modules. As the application of LED is getting more and more popular, how to increase the luminous efficiency of the LED or increase the brightness and uniformity of output light of the LED has become a prominent task and development goal to the industries. Through suitable design change of the LED structure, the luminous efficiency, brightness and uniformity of the LED can be effectively and significantly improved.

According to the current technology of LED structure, the positive (or the p-type) electrode is disposed above the entire structure. The positive electrode is normally made from non-transparent elements. When a voltage is applied so that a current is inputted between the positive (or the p-type) terminal and the negative (or the n-type) terminal to illuminate the PN junction between the P type semiconductor and the N type semiconductor, the elements of the positive electrode may block the light emitted by the PN junction and deteriorate luminous efficiency. Therefore, how to provide an LED structure, which sprays the current inputted to the positive electrode so that the current is fully conducted to illuminate the PN junction and at the same time effectively avoids the light being blocked by the positive electrode, has become a prominent direction when it comes to the improvement in luminous efficiency.

More detail description, Taiwanese Patent Publication No. I344221 “Gallium Nitride LED and Manufacturing Method Thereof” discloses an LED structure capable of increasing LED luminous brightness. Referring to FIG. 1, a structural diagram of a gallium nitride LED of the said patent is shown. As illustrated in the diagram, the gallium nitride LED structure 120 mainly includes a substrate 100, an n-type semiconductor layer 102, an active layer 104, a p-type semiconductor layer 106, a transparent contact layer 112, an insulating current blocking layer 110, a p-type electrode pad 114 and an n-type electrode pad 116. The stacking of elements is illustrated in the diagram.

As described above, because the insulating current blocking layer 110 is insulating and disposed under the p-type electrode pad 114, and the transparent contact layer 112 interposed between the p-type electrode pad 114 and the current blocking layer 110 forms a conduction path through which the current is inputted to the structure. At the same time, due to the blocking by the insulating current blocking layer 110, the inputted current sprays to the outside of the insulating current blocking layer 110 from the transparent contact layer 112 and is effectively scattered. The LED structure is capable of spreading the inputted current and improving the luminous efficiency at the PN junction or the active layer 104. However, the manufacturing method of the LED structure requires one more process for forming the insulating current blocking layer 110, hence increasing the time and cost required in the manufacturing process.

### SUMMARY OF THE INVENTION

The invention is directed to a light-emitting diode (LED) structure and a manufacturing method thereof. Through an etching process using photolithography technology and the high resistance between the positive electrode and the junction underneath, the input current is spread and conducted, hence reducing the time and cost required in the manufacturing process

According to one embodiment of the present invention, light-emitting diode (LED) structure is provided. The structure includes a semiconductor substrate, a first type semiconductor layer, a light-emitting layer, a second type semiconductor layer, an electrode contact layer, a positive electrode, and a negative electrode. The first type semiconductor layer is formed on the semiconductor substrate. The light-emitting layer is formed on partial surface of the first type semiconductor layer. The second type semiconductor layer corresponds to a top surface of the light-emitting layer and is formed on the light-emitting layer. The electrode contact layer is formed on the second type semiconductor layer and has a first opening exposing partial surface of the second type semiconductor layer. The positive electrode corresponds to the first opening and is formed on the exposed surface of the second type semiconductor layer. The negative electrode is formed on the surface of the first type semiconductor layer not covered by the light-emitting layer.

According to another embodiment of the present invention, manufacturing method of an LED structure is provided. The method comprises steps of providing a semiconductor substrate; forming a stacking layer formed by a first type semiconductor layer, a light-emitting layer, a second type semiconductor layer and an electrode contact layer in sequence on the semiconductor substrate, wherein the stacking layer has a first opening which penetrates the electrode contact layer and exposes partial of the second type semiconductor layer; inserting a metal plug in the first opening, forming a positive electrode on the exposed surface of the second type semiconductor layer; patterning the stacking layer, removing partial of the first type semiconductor layer, the light-emitting layer, the second type semiconductor layer and the electrode contact layer to form a platform structure in a light-emitting area, and exposing partial surface of the first type semiconductor layer in a non-light-emitting area; and forming a negative electrode on the exposed surface of the first type semiconductor layer.

According to an alternate embodiment of the present invention, manufacturing method of an LED structure, the method comprises steps of providing a semiconductor substrate; forming a stacking layer formed by a first type semiconductor layer, a light-emitting layer, a second type semiconductor layer, an electrode contact layer and a transparent electrode layer in sequence on the semiconductor substrate, wherein the stacking layer has a second opening which penetrates the transparent electrode layer and the electrode contact layer and exposes partial surface of the second type semiconductor layer; inserting a metal plug in the second opening and forming a positive electrode on the exposed surface of the second type semiconductor layer; patterning the stacking layer, removing a part of the first type semiconductor layer, the light-emitting layer, the second type semiconductor layer, the transparent electrode layer and the electrode contact layer to form a platform structure in a light-emitting area, and exposing partial surface of the first type semiconductor layer in a non-light-emitting area; and forming a negative electrode on the exposed surface of the first type semiconductor layer.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a structural diagram of a conventional gallium nitride LED;

FIGS. 2(a) to 2(d) are procedures of a manufacturing method of an LED structure according to a first embodiment of the present invention; and

FIGS. 3(a) to 3(d) are procedures of a manufacturing method of an LED structure according to a second embodiment of the present invention.

### DETAILED DESCRIPTION OF THE INVENTION

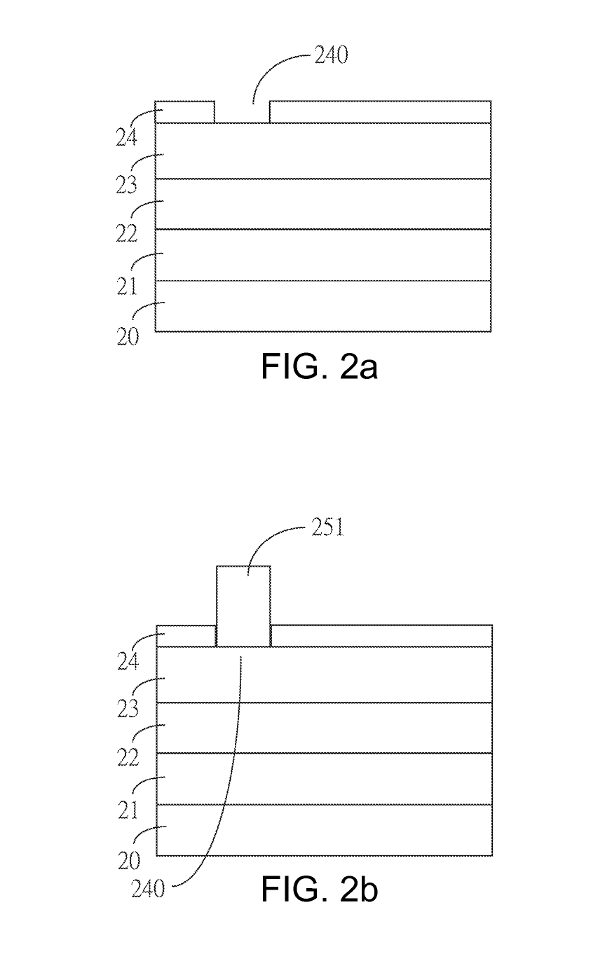

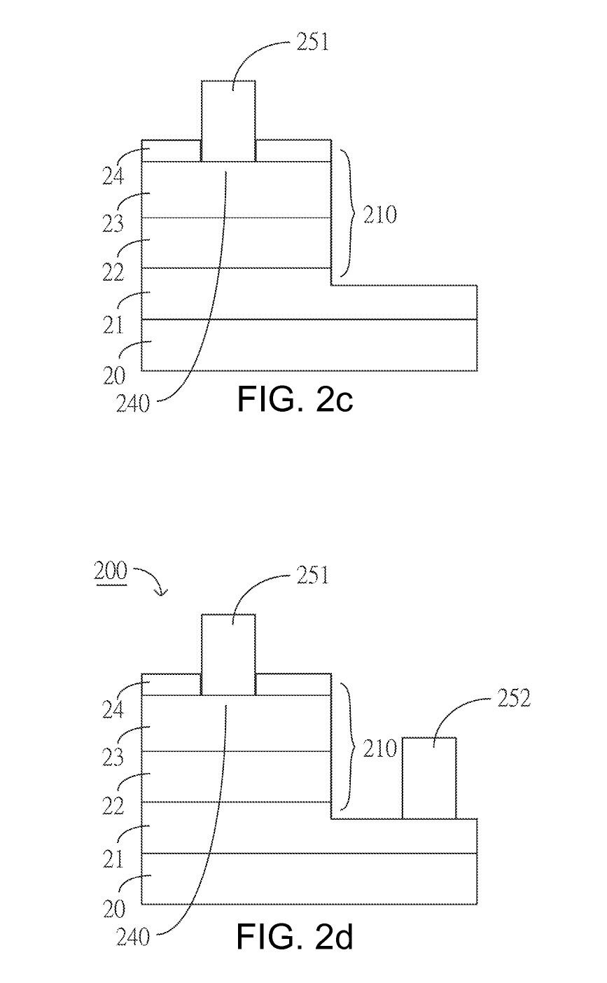

The present invention is exemplified by a first embodiment disclosed below. Referring to FIGS. 2(a) to 2(d), procedures of a manufacturing method of an LED structure according to a first embodiment of the present invention are shown. Refer to FIG. 2(a). Firstly, a semiconductor substrate 20 is provided, and a first type semiconductor layer 21, a light-emitting layer 22, a second type semiconductor layer 23 and an electrode contact layer 24 are formed on the semiconductor substrate 20 in sequence. As illustrated in the diagram, the electrode contact layer 24 is formed on the second type semiconductor layer 23, and a first opening 240 penetrates the electrode contact layer 24 to expose a part of the second type semiconductor layer 23.

In the manufacturing process, the electrode contact layer 24 is correspondingly formed on the entire upper surface of the second type semiconductor layer 23, and then a first opening 240 is formed at a designated position by an etching process with the definition of a photoresist pattern. Thus, a stacking layer is formed by stacking the electrode contact layer 24 with the first opening 240 formed therein, the first type semiconductor layer 21, the light-emitting layer 22 and the second type semiconductor layer 23 in sequence.

In the present embodiment, the first type semiconductor layer 21 is realized by an n-type gallium nitride (GaN) structure, the second type semiconductor layer 23 is realized by a p-type gallium nitride (GaN) structure, and the electrode contact layer 24 is realized by a p+ type gallium nitride (GaN) structure having high doping concentration. The concentration of the electrode contact layer 24 can be larger than 1×10²⁰(cm⁻³), so that the junction between the electrode contact layer 24 and the second type semiconductor layer 23 has lower contact resistance. In addition, the light-emitting layer 22 is realized by a multi-quantum well (MQW) structure layer for increasing the luminous efficiency when current flows at the PN junction.

Secondly, refer to FIG. 2(b). A positive electrode 251 corresponding to the first opening 240 is formed on the exposed surface of the second type semiconductor layer 23. In the present embodiment, the thickness of the electrode contact layer 24 used as a current spreading layer is about several hundred angstroms (A) such as 100A to 400A. For the positive electrode 251 to be effectively fixed in the first opening 240, a metal plug (not illustrated) is inserted in the first opening 240 (such as the exposed surface of the second type semiconductor layer 23 and the sidewalls of the first opening 240) beforehand, so that the positive electrode 251 formed on the surface of the second type semiconductor layer 23 may be fixed by the metal plug disposed underneath.

As described above, because the positive electrode 251 used for current conduction is made of a metal and contacts the second type semiconductor layer 23 disposed underneath, the junction between the positive electrode 251 and the second type semiconductor layer 23 has higher contact resistance. In other words, the junction forms a Schottky contact or Schottky barrier and can be used as a current blocking structure. Given that the resistance at the two sides of the junction is relative lower than the high resistance underneath the positive electrode 251, the current inputted to the positive electrode 251 is spread to the electrode contact layer 24 at the two sides of the positive electrode 251. Therefore, the electrode contact layer 24 can be used as a current spreading layer.

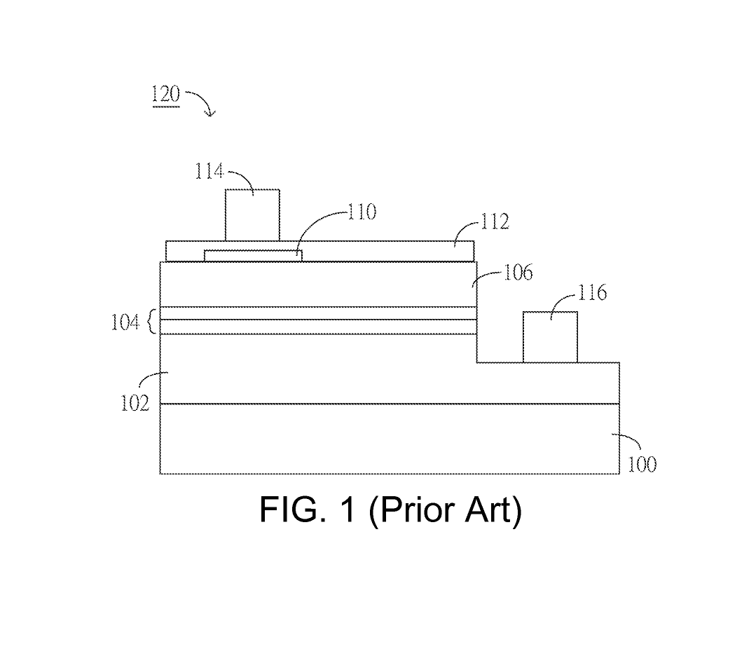

Referring to FIG. 2(c), a part of the first type semiconductor layer 21, the light-emitting layer 22, the second type semiconductor layer 23 and the electrode contact layer 24 is removed to form a platform structure (mesa) 210 as illustrated in the diagram. The platform structure 210 can be formed in a manner similar to the prior art as illustrated in FIG. 1. That is, partial stacking of an entire LED structure is removed. The light-emitting area in which the light-emitting layer 22 is located forms a protrusion, that is, the platform structure 210. The exposed surface of the first type semiconductor layer 21 forms a non-light-emitting area in which a negative electrode can be disposed subsequently. The non-light-emitting area contacts the first type (n-type) semiconductor layer 21 for conducting the current.

In the present embodiment, the platform structure 210 is formed by using photolithography technology. To put it in greater details, the stacking layer, consisting of the first type semiconductor layer 21, the light-emitting layer 22, the second type semiconductor layer 23 and the electrode contact layer 24 stacked to each other, is patterned and etched, so that the pattern of the mask or photoresist used in photolithography technology is transferred to the stacking layer. The protrusion formed by the etching process becomes the platform structure 210. Like the prior art, in the present embodiment, the etching thickness of the first type semiconductor layer 21 is determined according to the needs of the manufacturing process and is controlled by adjusting the etching time.

Referring to FIG. 2(d), a negative electrode 252 is formed on the exposed partial surface of the first type semiconductor layer 21. Due to the high resistance underneath the positive electrode 251, the current inputted to the structure through the positive electrode 251 is spread to the two sides of the positive electrode and then is conducted to the outside through the negative electrode 252. Consequently, the density of the current inside the light-emitting area is increased, the light generated by the light-emitting layer 22 is uniformly emitted and the luminous efficiency is effectively increased.

Therefore, the last configuration of FIG. 2(d) is the light-emitting diode (LED) structure 200 manufactured by the manufacturing method of an LED structure according to a first embodiment of the present invention. As illustrated in the diagram, the LED structure 200 includes a semiconductor substrate 20, a first type semiconductor layer 21, a light-emitting layer 22, a second type semiconductor layer 23, an electrode contact layer 24, a positive electrode 251 and a negative electrode 252. The first type semiconductor layer 21 is formed on the semiconductor substrate 20. The light-emitting layer 22 is formed on partial surface of the first type semiconductor layer 21. The second type semiconductor layer 23 corresponds to a top surface of the light-emitting layer 22 and is formed on the light-emitting layer 22. The electrode contact layer 24 having the first opening 240 is formed on the second type semiconductor layer 23 for exposing partial surface of the second type semiconductor layer 23. The positive electrode 251 corresponds to the first opening 240 and is formed on the exposed surface of the second type semiconductor layer 23. The negative electrode 252 is formed on the surface of the first type semiconductor layer 21 not covered by the light-emitting layer 22.

The present invention may also achieve similar features and effects of the first embodiment with suitable modifications. For example, the first type semiconductor layer 21 may be an n-type nitride containing gallium, the second type semiconductor layer 23 may be a p-type nitride containing gallium, and the electrode contact layer 24 may be a p+ type nitride containing gallium having high doping concentration, and these materials are not limited to gallium nitride (GaN). In the last configuration as illustrated in FIG. 2(d) of the first embodiment, the positive electrode 251 corresponds to the dimension of the first opening 240. In other embodiments, the positive electrode may cover partials part of the electrode contact layer 24. That is, the area of the top portion of the positive electrode is larger than the dimension of the first opening 240 for better spreading the current. Based on the first embodiment, the present invention may further add other elements to the manufacturing process to enhance the effect of current spreading.

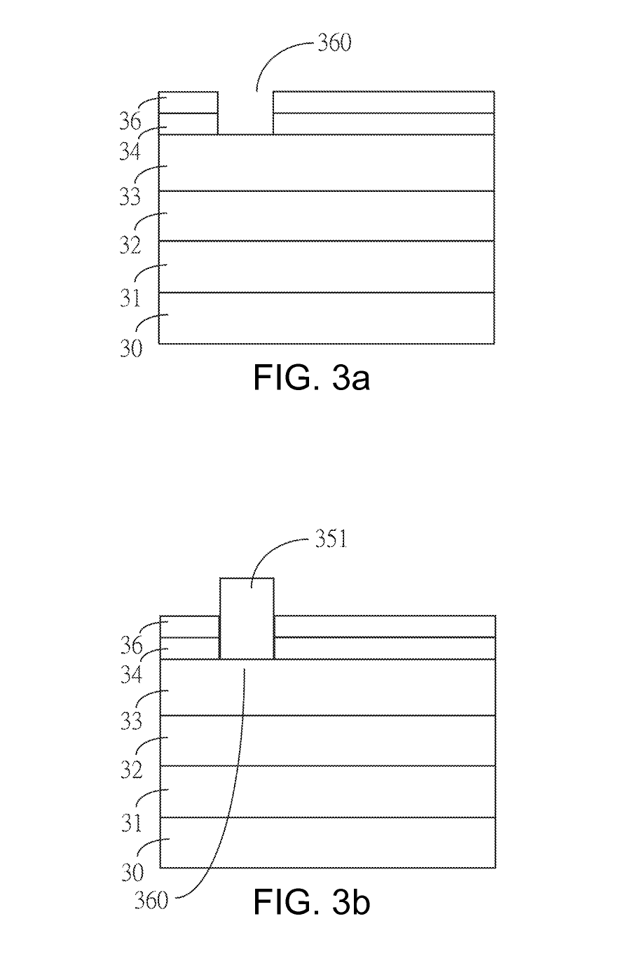

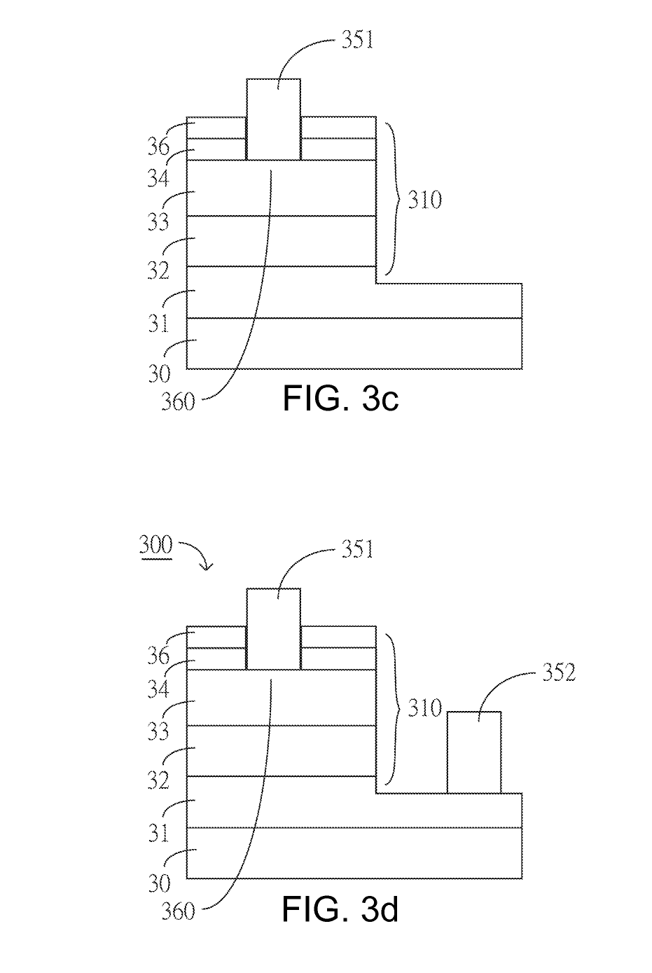

The present invention is further exemplified by a second embodiment disclosed below. Referring to FIGS. 3(a) to 3(d), procedures of a manufacturing method of an LED structure according to a second embodiment of the present invention are shown. The manufacturing process of the second embodiment is different from that of the first embodiment in the use of a transparent electrode layer. The corresponding positions of elements, the materials and associated features, and even the possible modifications (such as the covering of the positive electrode on the top layer) of the second embodiment are identical to that of the first embodiment. Referring to FIG. 3(a), a first type semiconductor layer 31, a light-emitting layer 32, a second type semiconductor layer 33, an electrode contact layer 34 and a transparent electrode layer 36 are formed on a semiconductor substrate 30 in sequence. As illustrated in the diagram, the transparent electrode layer 36 is formed on the electrode contact layer 34. In the present embodiment, a second opening 360 penetrates both the transparent electrode layer 36 and the electrode contact layer 34, and exposes partial surface of the second type semiconductor layer 33.

In the present embodiment, a stacking layer is formed by stacking the transparent electrode layer 36 and the electrode contact layer 34 having the second opening 360, the first type semiconductor layer 31, the light-emitting layer 32 and the second type semiconductor layer 33 formed in sequence. The second opening 360 may be formed by an etching process with the definition of a photoresist pattern for etching the transparent electrode layer 36 and the electrode contact layer 34 directly.

In other possible modifications of the embodiments of the invention, an electrode contact layer may be etched to form a first opening 240 as illustrated in FIG. 1(a) like the first embodiment, and then a transparent electrode layer having a second opening (not illustrated in the diagram) is formed on the electrode contact layer, wherein the dimension of the second opening corresponds to the dimension of the first opening 240. Alternatively, a transparent electrode layer is etched to form a second opening (not illustrated in the diagram), and then the electrode contact layer underneath the transparent electrode layer is etched to form a first opening 240 as illustrated in FIG. 1(a). Likewise, the dimension of the second opening corresponds to the dimension of the first opening 240, so that the positive electrode corresponds to the first opening and the second opening and is formed on the exposed surface of the second type semiconductor layer 33.

Referring to FIG. 3(b), a positive electrode 351 corresponds to the second opening 360 and is formed on the exposed surface of the second type semiconductor layer 33. Like the first embodiment, a metal plug (not illustrated in the diagram) is inserted in the second opening 360 beforehand, so that the positive electrode 351 formed on the second type semiconductor layer 33 may be fixed by the metal plug disposed underneath.

In the present embodiment, the transparent electrode layer 36 may also be used as a current spreading layer for increasing the effect of current spreading. To put it in greater details, the transparent electrode layer 36 may be indium tin oxide (ITO) or indium zinc oxide (IZO). Likewise, the junction between the positive electrode 351 and the second type semiconductor layer 33 has higher contact resistance. The current inputted to the positive electrode 351 is spread to the transparent electrode layer 36 at the two sides of the positive electrode 351 to achieve better effect of current spreading, and then is conducted downward through the electrode contact layer 34.

Referring to FIG. 3(c), a part of the first type semiconductor layer 31, the light-emitting layer 32, the second type semiconductor layer 33, the electrode contact layer 34 and the transparent electrode layer 36 is removed by photolithography technology to form a platform structure (mesa) 310 as illustrated in the diagram. Likewise, the light-emitting area in which the light-emitting layer 32 is located forms a protrusion, that is, the platform structure 310. The partial exposed surface of the first type semiconductor layer 31 is a non-light-emitting area in which a negative electrode can be disposed subsequently.

Referring to FIG. 3(d), a negative electrode 352 is formed on partial exposed surface of the first type semiconductor layer 31. The last configuration of FIG. 3(d) is the light-emitting diode (LED) structure 300 manufactured by the manufacturing method of an LED structure according to a second embodiment of the present invention.

To summarize, the LED structure of the present invention spreads and conducts the inputted current through an etching process using photolithography technology and the high resistance between the positive electrode and the junction underneath. In comparison to the prior art, the present invention not only spreads and conducts the current to effectively increase luminous efficiency, but further simplifies the manufacturing process of forming the insulating current blocking layer and reduces both the required manufacturing time and the cost. Therefore the present invention effectively resolves the problems encountered in the prior art and successfully achieves the main objects of the invention.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light-emitting diode (LED) structure, comprising:
a semiconductor substrate;
a first type semiconductor layer formed on the semiconductor substrate;
a light-emitting layer formed on partial surface of the first type semiconductor layer;
a second type semiconductor layer corresponding to a top surface of the light-emitting layer and formed on the light-emitting layer;
an electrode contact layer formed on the second type semiconductor layer, wherein the electrode contact layer has a first opening exposing partial surface of the second type semiconductor layer;
a positive electrode corresponding to the first opening and formed on the exposed surface of the second type semiconductor layer; and
a negative electrode formed on the surface of the first type semiconductor layer not covered by the light-emitting layer.

2. The LED structure according to claim 1, further comprising a transparent electrode layer formed on the electrode contact layer and having a second opening corresponding to the dimension of the first opening, so that the positive electrode corresponds to the first opening and the second opening and is formed on the exposed surface of the second type semiconductor layer.

3. The LED structure according to claim 2, wherein the transparent electrode layer is indium tin oxide (ITO) or indium zinc oxide (IZO).

4. The LED structure according to claim 1, wherein the positive electrode further covers a part of the electrode contact layer.

5. The LED structure according to claim 2, wherein the positive electrode further covers a part of the transparent electrode layer.

6. The LED structure according to claim 1, wherein the electrode contact layer is a p+ type nitride containing gallium having high doping concentration.

7. The LED structure according to claim 6, wherein the electrode contact layer is a p+ type gallium nitride (GaN) having high doping concentration.

8. The LED structure according to claim 1, wherein the first type semiconductor layer is an n-type nitride containing gallium, and the second type semiconductor layer is a p-type nitride containing gallium.

9. The LED structure according to claim 8, wherein the first type semiconductor layer is an n-type gallium nitride, and the second type semiconductor layer is a p-type gallium nitride.

10. The LED structure according to claim 1, wherein the light-emitting layer is a multi-quantum well (MQW) structure layer.

11. A manufacturing method of an LED structure, the method comprises steps of:
providing a semiconductor substrate;
forming a stacking layer formed by a first type semiconductor layer, a light-emitting layer, a second type semiconductor layer and an electrode contact layer in sequence on the semiconductor substrate, wherein the stacking layer has a first opening which penetrates the electrode contact layer and exposes a part of the second type semiconductor layer;
inserting a metal plug in the first opening and forming a positive electrode on the exposed surface of the second type semiconductor layer;
patterning the stacking layer, removing a part of the first type semiconductor layer, the light-emitting layer, the second type semiconductor layer and the electrode contact layer to form a platform structure in a light-emitting area, and exposing partial surface of the first type semiconductor layer in a non-light-emitting area; and
forming a negative electrode on the exposed surface of the first type semiconductor layer.

12. The manufacturing method of an LED structure according to claim 11, wherein the positive electrode further covers a part of the electrode contact layer.

13. The manufacturing method of an LED structure according to claim 11, wherein the electrode contact layer is a p+ type nitride containing gallium having high doping concentration.

14. The manufacturing method of an LED structure according to claim 13, wherein the electrode contact layer is a p+ type gallium nitride having high doping concentration.

15. The manufacturing method of an LED structure according to claim 11, wherein the first type semiconductor layer is an n-type nitride containing gallium, and the second type semiconductor layer is a p-type nitride containing gallium.

16. The manufacturing method of an LED structure according to claim 15, wherein the first type semiconductor layer is an n-type gallium nitride (GaN) structure, and the second type semiconductor layer is a p-type gallium nitride (GaN) structure.

17. The manufacturing method of an LED structure according to claim 11, wherein the light-emitting layer is a multi-quantum well (MQW) structure layer.

18. A manufacturing method of an LED structure, the method comprises steps of:
providing a semiconductor substrate;
forming a stacking layer formed by a first type semiconductor layer, a light-emitting layer, a second type semiconductor layer, an electrode contact layer and a transparent electrode layer in sequence on the semiconductor substrate, wherein the stacking layer has a second opening which penetrates the transparent electrode layer and the electrode contact layer and exposes partial surface of the second type semiconductor layer;
inserting a metal plug in the second opening and forming a positive electrode on the exposed surface of the second type semiconductor layer;
patterning the stacking layer, removing a part of the first type semiconductor layer, the light-emitting layer, the second type semiconductor layer, the transparent electrode layer and the electrode contact layer to form a platform structure in a light-emitting area, and exposing partial surface of the first type semiconductor layer in a non-light-emitting area; and
forming a negative electrode on the exposed surface of the first type semiconductor layer.

19. The manufacturing method of an LED structure according to claim 18, wherein the transparent electrode layer is indium tin oxide (ITO) or indium zinc oxide (IZO).

20. The manufacturing method of an LED structure according to claim 18, wherein the positive electrode further covers a part of the transparent electrode layer.

21. The manufacturing method of an LED structure according to claim 18, wherein the electrode contact layer is a p+ type nitride containing gallium having high doping concentration.

22. The manufacturing method of an LED structure according to claim 21, wherein the electrode contact layer is a p+ type gallium nitride having high doping concentration.

23. The manufacturing method of an LED structure according to claim 18, wherein the first type semiconductor layer is an n-type nitride containing gallium, and the second type semiconductor layer is a p-type nitride containing gallium.

24. The manufacturing method of an LED structure according to claim 23, wherein the first type semiconductor layer is an n-type gallium nitride (GaN) structure, and the second type semiconductor layer is a p-type gallium nitride (GaN) structure.

25. The manufacturing method of an LED structure according to claim 18, wherein the light-emitting layer is a multi-quantum well (MQW) structure layer.
